(19) United States
(12) Patent Application Publication
(10) Pub. No.: US 2020/0264269 A1
(43) Pub. Date: Aug. 20, 2020

(54) RADAR DATA PROCESSING METHOD AND DEVICE AND MOBILE PLATFORM

(71) Applicant: SZ DJI TECHNOLOGY CO., LTD., Shenzhen (CN)

(72) Inventors: Lei ZHU, Shenzhen (CN); Qingdong YU, Shenzhen (CN); Wei XIAO, Shenzhen (CN)

(21) Appl. No.: 16/856,747

(22) Filed: Apr. 23, 2020

Related U.S. Application Data
(63) Continuation of application No. PCT/CN2017/108026, filed on Oct. 27, 2017.

(51) Int. Cl. G01S 7/03; G01S 13/933; H03M 7/40

(52) U.S. Cl. CPC G01S 7/03; H03M 7/4075; G01S 13/933

(57) ABSTRACT

A radar data processing method is provided. The method includes dividing to-be-compressed radar data into groups, determining encoding parameters of each group according to at least one radar data in each group, and encoding each radar data in each group according to the encoding parameters of each group, to obtain encoded radar data.

### CROSS-REFERENCE TO RELATED APPLICATION

This application is a continuation of International Application No. PCT/CN2017/108026, filed on Oct. 27, 2017, the entire content of which is incorporated herein by reference.

### TECHNICAL FIELD

The present disclosure relates to the field of unmanned aerial vehicle technology and, more particularly, to a radar data processing method, device and mobile platform thereof.

### BACKGROUND

In the existing technologies, mobile platforms, such as unmanned aerial vehicles and mobile robots, are generally provided with radar devices. The radar devices may be configured to detect target objects around the mobile platforms, and detect the distance of the target objects from the mobile platforms.

An unmanned aerial vehicle may process on-board the radar data measured by a radar device during the flight, or store on-board the radar data measured by the radar device. After the unmanned aerial vehicle returns to the ground, a ground device performs an analysis on the radar data stored by the unmanned aerial vehicle.

When a mobile platform stores the radar data on-board, it is necessary to compress the radar data. However, the existing technologies lack a method for efficiently compressing the radar data.

### SUMMARY

In accordance with the present disclosure, there is provided a radar data processing method. The method includes dividing to-be-compressed radar data into groups, determining encoding parameters of each group according to at least one radar data in each group, and encoding each radar data in each group to obtain encoded radar data according to the encoding parameters of each group.

Also in accordance with the disclosure, there is provided a radar data processing device. The radar data processing device includes a processor. The processor is configured to divide to-be-compressed radar data into groups, determine encoding parameters of each group according to at least one radar data in each group, and encode each radar data in each group to obtain encoded radar data according to the encoding parameters of each group.

Also in accordance with the disclosure, there is provided a mobile platform. The mobile platform includes a fuselage, a propulsion system installed on the fuselage for providing propulsion for motion, a radar device for detecting target objects around the mobile platform, and a radar data processing device. The radar data processing device includes a processor configured to divide to-be-compressed radar data into groups, determine encoding parameters of each group according to at least one radar data in each group, and encode each radar data in each group to obtain encoded radar data according to the encoding parameters of each group.

### BRIEF DESCRIPTION OF THE DRAWINGS

FIG. 1 is a flowchart of a radar data processing method according to an embodiment of the present disclosure;

FIG. 2 is a schematic diagram of an encoding and storage process according to an embodiment of the present disclosure;

FIG. 3 is a schematic diagram of a decoding process according to an embodiment of the present disclosure;

FIG. 4 is a flowchart of a radar data processing method according to another embodiment of the present disclosure;

FIG. 5 is a schematic diagram of a ZigZag scan according to an embodiment of the present disclosure;

FIG. 6 is a schematic diagram of a matrix of ZigZag scan according to an embodiment of the present disclosure;

FIG. 7 is a flowchart of a radar data processing method according to another embodiment of the present disclosure;

FIG. 8 is a schematic structural diagram of a radar data processing device according to an embodiment of the present disclosure; and

FIG. 9 is a schematic structural diagram of an unmanned aerial vehicle according to an embodiment of the present disclosure.

### DETAILED DESCRIPTION OF THE EMBODIMENTS

The technical solutions in the embodiments of the present disclosure will be made in detail hereinafter with reference to the accompanying drawings in the disclosed embodiments. It is to be understood that the disclosed embodiments are only a part, but not all, of the embodiments of the present disclosure. Based on the embodiments of the present disclosure, all other embodiments obtained by a person of ordinary skill in the art without creative efforts shall still fall within the protection scope of the present disclosure.

It should be noted that when a component is called “fixed to” another component, it may be directly on a surface of another component or located at the center of another component. When a component is called “connected to” another component, it may be directly connected to another component or may also be located at the center of another component.

Unless defined otherwise, all technical and scientific terms used herein have the same meaning as commonly understood by one of ordinary skill in the relevant art. The terms used in the description of the present disclosure are merely for the purpose of describing specific embodiments, and are not intended to limit the present disclosure. The term “and/or” as used herein includes any and all combinations of one or more of the associated listed items.

Hereinafter, some embodiments of the present disclosure will be made in detail with reference to the accompanying drawings. Unless there is a clear conflict, the following embodiments and features in these embodiments may be combined with each other.

An embodiment of the present disclosure provides a radar data processing method. FIG. 1 is a flowchart of a radar data processing method according to an embodiment of the present disclosure. As shown in FIG. 1, the method in the disclosed embodiment may include:

Step S101: Divide to-be-compressed radar data into groups.

Generally, mobile platforms, such as unmanned aerial vehicles, mobile robots and vehicles, are equipped with radar devices, which may detect obstacles around the mobile platforms. For example, a radar device may detect the position, speed, and attitude of an obstacle related to a mobile platform. The mobile platform performs obstacle avoidance and route planning based on the radar data measured by the radar device.

Take an unmanned aerial vehicle (UAV) as an example. When the UAV is in flight, the UAV may perform an on-board processing or analysis on the radar data measured by the radar device. Alternatively, the UAV may store on-board the radar data measured by the radar device. When the UAV returns to the ground, a ground-side device performs an off-board processing or analysis on the radar data stored by the UAV. In addition, after the UAV stores on-board the radar data measured by the radar device, the UAV may also send the radar data stored on-board to a ground-side device, to allow the ground-side device to process or analyze the radar data stored on-board by the UAV. The processed or analyzed result is then returned back to the UAV.

Since the amount of radar data measured by the radar device may be large, in order to save the storage space of the UAV, when the UAV stores the radar data on-board, the radar data needs to be compressed.

When the UAV needs to compress the radar data, the UAV may first divide the to-be-compressed radar data into groups. Optionally, the radar device installed on the UAV is a millimeter-wave radar device, or may also be other types of radar devices, which are not specifically limited in the disclosed embodiment. The UAV may compress the original radar data measured by the millimeter-wave radar device and store the compressed data. The UAV may also perform a decorrelation transform on the original radar data measured by the millimeter-wave radar device to obtain the decorrelation-transformed radar data. The decorrelation-transformed radar data is then compressed and stored.

For example, the UAV may perform a two-dimensional Fast Fourier Transform (FFT) or a Discrete Cosine Transform (DCT) and the like on the original radar data measured by the millimeter-wave radar device, to obtain frequency point coefficients of the original radar data. The frequency point coefficients of the original radar data are then compressed and stored.

Assume that the amount of original radar data measured by the millimeter-wave radar device is large. The UAV may divide the original radar data into groups according to the scale of the two-dimensional FFT. For example, if the scale of the two-dimensional FFT is M*N, the UAV may divide the original radar data into groups according to the magnitude of M*N, and perform the two-dimensional FFT on the original radar data with a unit size of M*N. It may be understood that the original radar data is time-domain information. After the two-dimensional FFT, the original radar data will be converted into frequency-domain information. That is, after the two-dimensional FFT, a M*N number of original radar data will be converted into a M*N number of frequency point coefficients. Next, the UAV compresses the M*N number of frequency point coefficients by using the M*N number of frequency point coefficients as a unit. Specifically, the UAV uses the M*N number of frequency point coefficients as the to-be-compressed radar data, and divides the M*N number of frequency point coefficients into groups. The disclosed embodiment does not limit the specific grouping method. After grouping, each group includes at least one frequency point coefficient. In addition, the frequency point coefficients included in each group may be the same or different.

Step S102: Determine the encoding parameters of each group according to at least one radar data in each group.

After the UAV divides the M*N number of frequency point coefficients into groups, the frequency point coefficients in each group need to be encoded. Prior to encoding, the encoding parameters of each group need to be determined. The disclosed embodiment does not intend to limit a specific encoding method. Optionally, the UAV uses a K-th Exp-Golomb encoding method to encode the frequency point coefficients in each group. Before performing the K-th Exp-Golomb encoding on the frequency point coefficients in each group, it is necessary to determine the encoding parameters, such as parameter K, for each group.

Specifically, the UAV determines the parameter K corresponding to each group when performing the K-th Exp-Golomb encoding on each group according to the frequency point coefficients in each group.

Step S103: Encode each radar data in each group according to the encoding parameters of each group to obtain the encoded radar data.

After the UAV determines the parameter K corresponding to each group, the K-th Exp-Golomb encoding is performed on each frequency point coefficient in each group according to the parameter K corresponding to each group. The encoded radar data includes parameter K corresponding to each group, and encoded code words after the K-th Exp-Golomb encoding of each frequency point coefficient in each group.

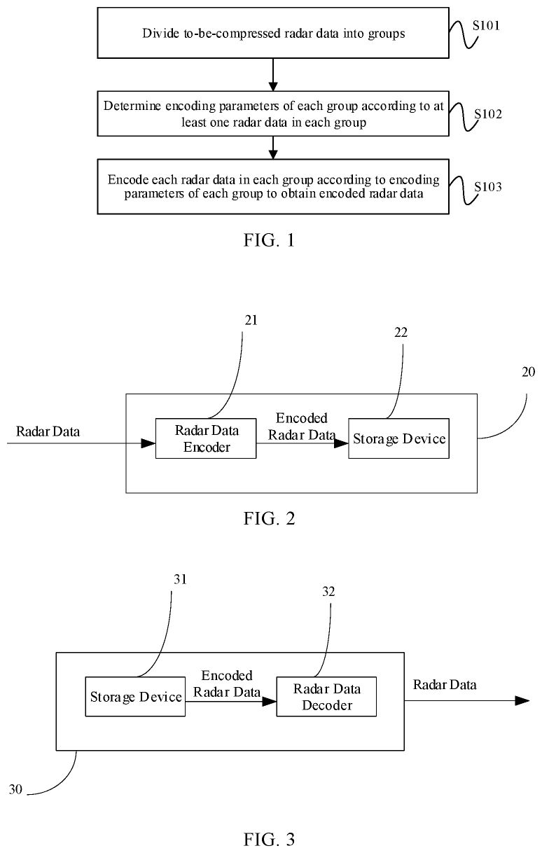

Compared to the existing technologies, the disclosed mobile platforms, such as UAVs, mobile robots, vehicles, etc., are equipped with a recorder 20, as shown in FIG. 2. The recorder 20 includes a radar data encoder 21 and a storage device 22. The input for the radar data encoder 21 is radar data. The radar data may be the frequency point coefficients obtained by performing the FFT on the original radar data measured by the millimeter-wave radar device, or the original radar data itself. The radar data encoder 21 encodes the frequency point coefficients or original radar data to obtain encoded radar data, and stores the encoded radar data on the storage device 22.

A mobile platform may perform a wired or wireless communication with a ground off-board analysis device after the mobile platform stops working or stops moving or while the mobile platform is still working or moving. As shown in FIG. 3, 30 represents a parser of a ground off-board analysis device. The parser 30 includes a storage device 31 and a radar data decoder 32. For example, the mobile platform is specifically a UAV. When the UAV returns to the ground, the UAV performs a wired or wireless communication with the ground off-board analysis device, to allow the UAV to send the encoded radar data, stored on the storage device 22 shown in FIG. 2, to the storage device 31 of the ground off-board analysis device. The radar data decoder 32 then obtains the encoded radar data from the storage device 31, and decodes the encoded radar data to restore the radar data, to allow the off-board analysis device to analyze or process the radar data decoded by the radar data decoder 32. The disclosed embodiment does not limit the specific radar data analysis or processing process performed by the ground off-board analysis device.

In the disclosed embodiment, the to-be-compressed radar data is divided into groups. The encoding parameters of each group are determined according to at least one radar data in each group. According to the encoding parameters of each group, each radar data in each group is encoded to obtain the encoded radar data. By encoding the radar data in groups, the encoding efficiency of each group may be improved, thereby achieving an efficient compression of the radar data.

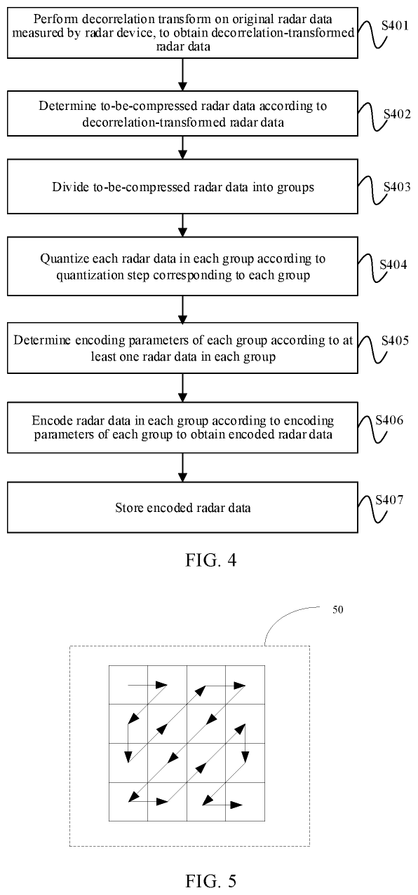

An embodiment of the present disclosure provides a radar data processing method. FIG. 4 is a flowchart of a radar data processing method according to another embodiment of the present disclosure. As shown in FIG. 4, based on the embodiment shown in FIG. 1, the method in this embodiment may include:

Step S401: Perform a decorrelation transform on the original radar data measured by the radar device, to obtain the decorrelation-transformed radar data.

In the disclosed embodiment, the decorrelation transform may specifically be a two-dimensional FFT, and the decorrelation-transformed radar data may specifically be frequency point coefficients after the two-dimensional FFT. In some embodiments, the decorrelation transform may be performed in a way other than the two-dimensional FFT.

For example, a two-dimensional FFT is performed on the original radar data measured by the radar device to obtain the frequency point coefficients of the original radar data.

Step S402: Determine to-be-compressed radar data according to the decorrelation-transformed radar data.

The process of determining to-be-compressed radar data according to the decorrelation-transformed radar data includes the following feasible implementations:

Implementation 1: Determining the decorrelation-transformed radar data as the to-be-compressed radar data. For example, after performing the two-dimensional FFT on the original radar data measured by the radar device, the frequency point coefficients of the original radar data are determined to be the to-be-compressed radar data.

Implementation 2: Ranking the decorrelation-transformed radar data to obtain ranked radar data, and determining the ranked radar data as the to-be-compressed radar data. For example, after performing the two-dimensional FFT on the original radar data measured by the radar device, the frequency point coefficients of the original radar data are ranked to obtain ranked frequency point coefficients, which are then used as the to-be-compressed radar data.

Specifically, the process of ranking the decorrelation-transformed radar data to obtain the ranked radar data includes: ranking the decorrelation-transformed radar data according to the frequency of the decorrelation-transformed radar data to obtain the ranked radar data. For example, when ranking the frequency point coefficients of the original radar data, the frequency point coefficients may be ranked according to the magnitude of the frequencies. Optionally, the frequency point coefficients may be ranked in an order of low-to-high frequency, or in an order of high-to-low frequency.

Specifically, the process of ranking the decorrelation-transformed radar data to obtain the ranked radar data includes: ranking the decorrelation-transformed radar data in an order of low-to-high frequency to obtain the ranked radar data. Assume that the energy amplitudes of the adjacent frequency points of the radar data are close and related. By ranking the frequency point coefficients in an order of low-to-high frequency, it means that the energy amplitudes of adjacent frequency points of the radar data are also ranked. Generally, the energy amplitudes of low and middle frequency points are larger than the energy amplitudes of high frequency points.

Specifically, the process of ranking the decorrelation-transformed radar data in an order of low-to-high frequency includes: performing a ZigZag scan on the decorrelation-transformed radar data in an order of low-to-high frequency. For example, when ranking the frequency point coefficients in an order of low-to-high frequency, a ZigZag scan may be specifically performed on the frequency point coefficients in an order of low-to-high frequency. As shown in FIG. 5, 50 represents a 4*4 matrix. It should be noted that the size of the matrix illustrated in the figure is merely for illustrative purposes, which is not limited by the present disclosure. When performing a ZigZag scan on the matrix 50, the matrix 50 may be scanned according to the arrow shown in FIG. 5. For example, if the matrix 50 is specifically the matrix shown in FIG. 6, the order of the scanning, obtained by performing the ZigZag scan on the matrix 50, is 1, 5, 3, 9, 7, 3, 9, 5, 4, 7, 3, 6, 6, 4, 1, 3. As shown in FIG. 6, the element of the first row and the first column of the matrix 50 is 1, the element of the first row and the second column is 5, and the element of the second row and the first column is 3. In the matrix 50, the first-row element 1 in the first column, the first-row element 5 in the second column, and the second-row element 3 in the first column are adjacent. After performing the ZigZag scan on the matrix 50, the first-row element 1 in the first column, the first-row element 5 in the second column, and the second-row element 3 in the first column are also ranked close to each other. In the disclosed embodiment, the ZigZag scan is performed on the frequency point coefficients in an order of low-to-high frequency, so that the adjacent frequency points are ranking close to each other after the scanning.

Step S403: Divide the to-be-compressed radar data into groups.

Optionally, if the ranked frequency point coefficients are used as the to-be-compressed radar data, when the ranked frequency point coefficients are grouped, frequency point coefficients with frequencies close to each other may be grouped into one group. The number of frequency point coefficients in each group may be the same or different.

Step S404: Quantize each radar data in each group according to the quantization step corresponding to each group.

Because the frequency point coefficients in a group are close to each other, the frequency point coefficients in each group may be quantized. Each group may correspond to a quantization step. Specifically, the quantization step corresponding to each group may be the same or different, or the quantization step of some radar data within the same group may be different.

Step S405: Determine the encoding parameters of each group according to at least one radar data in each group.

The specific principles and implementations of Step S405 are similar to Step S102, details of which are not described again here.

Step S406: Encode the radar data in each group according to the encoding parameters of each group to obtain the encoded radar data.

The specific principles and implementations of Step S406 are similar to Step S103, details of which are not described again here.

Step S407: Store the encoded radar data.

In the disclosed embodiment, the decorrelation transform is performed on the original radar data measured by the radar device to obtain the decorrelation-transformed radar data. By compressing the decorrelation-transformed radar data, the compression efficiency of the radar data may be further improved.

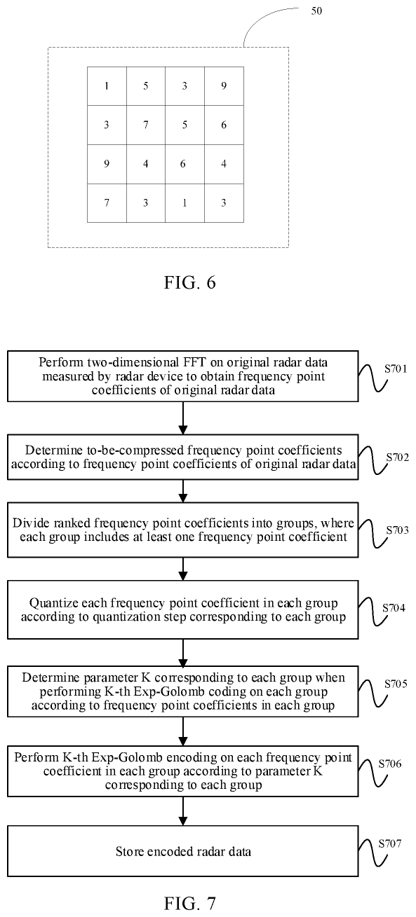

An embodiment of the present disclosure provides a radar data processing method. FIG. 7 is a flowchart of a radar data processing method according to another embodiment of the present disclosure. As shown in FIG. 7, on the basis of the foregoing embodiments, the method in this embodiment may include:

Step S701: Perform a two-dimensional FFT on the original radar data measured by the radar device to obtain frequency point coefficients of the original radar data.

Step S702: Determine to-be-compressed frequency point coefficients according to the frequency point coefficients of the original radar data.

Specifically, the process of determining the to-be-compressed frequency point coefficients according to the frequency point coefficients of the original radar data includes: ranking the frequency point coefficients of the original radar data to obtain ranked frequency point coefficients, and determining the ranked frequency point coefficients as the to-be-compressed frequency point coefficients. For example, the frequency point coefficients are ranked according to the magnitude of the frequencies. Optionally, the frequency point coefficients are ranked in an order of low-to-high frequency, or in an order of high-to-low frequency.

Specifically, the process of ranking the frequency point coefficients of the original radar data to obtain the ranked frequency point coefficients includes: ranking the frequency point coefficients of the original radar data in an order of low-to-high frequency to obtain ranked frequency point coefficients. Assume that the energy amplitudes of the adjacent frequency points of the radar data are close and related. By ranking the frequency point coefficients in an order of low-to-high frequency, it means that the energy amplitudes of adjacent frequency points of the radar data are also ranked.

Specifically, the process of ranking the frequency point coefficients of the original radar data in an order of low-to-high frequency includes: performing a ZigZag scan on the frequency point coefficients of the original radar data in an order of low-to-high frequency. For example, when the frequency point coefficients are ranked in an order of low-to-high frequency, a ZigZag scan may be performed on the frequency point coefficients in an order of low-to-high frequency, so that the adjacent frequency points are ranked close to each other after the ZigZag scan. That is, the coefficients of adjacent frequency points are ranked close to each other after the scanning.

Step S703: Divide the ranked frequency point coefficients into groups, where each group includes at least one frequency point coefficient.

In the disclosed embodiment, the purpose of grouping the ranked frequency point coefficients is to group the frequency points with close energy amplitudes into one group. The number of frequency point coefficients included in each group may be the same or different.

There may be multiple grouping methods for grouping the ranked frequency point coefficients, which are not specifically limited in the disclosed embodiment.

Step S704: Quantize each frequency point coefficient in each group according to the quantization step corresponding to each group.

Optionally, the quantization steps corresponding to different groups are different or the same, or the quantization steps for some frequency point coefficients in a same group are different.

In one example, the quantization step corresponding to each group is equal to Q. Assume that a frequency point coefficient before quantization is F, then the frequency point coefficient after quantization is denoted as FQ. In addition, the Q value may control the quantization error. When Q is 1, it is a lossless encoding, which means that a decoding terminal may reconstruct the data that is the same as the original data. When Q is not equal to 1, it is a lossy encoding. Under the lossless encoding, the compression ratio of a typical scenario is 30%-50%, which means that 50%-70% of storage space or corresponding recording time length is saved. Under the lossy encoding, each time the quantization step doubles, the average compression rate increases by 1 bit. Taking an original accuracy of 16-bit as an example, it saves 1/16 more on the basis of the original.

Step S705: Determine parameter K corresponding to each group when performing a K-th Exp-Golomb encoding on each group according to the frequency point coefficients in each group. Specifically, determining the parameter K corresponding to each group when performing the K-th Exp-Golomb encoding on each group according to the frequency point coefficients in each group includes: based on each frequency point coefficient in the group, determining the estimated value of the respective parameter K corresponding to each frequency point coefficient, and determining the parameter K corresponding to the group according to the estimated value of the respective parameter K corresponding to each frequency point coefficient in the group.

For example, a frequency point coefficient in a certain group is F before quantization, and the frequency point coefficient is FQ after quantization. The optimal parameter K corresponding to the frequency point coefficient FQ after quantization is determined according to the following logic equations. Assume that the optimal parameter K corresponding to FQ is denoted as Ke.

If (FQ==0)

Ke=0;

Else

Ke=log₂(FQ);

Assume that a group includes four frequency point coefficients F1, F2, F3, and F4. Before determining the parameter K corresponding to the group, first determine the optimal parameter K corresponding to F1, F2, F3, and F4 in the group, respectively. Specifically, the optimal parameters K corresponding to F1, F2, F3, and F4 are determined according to the above logic equations. Assume that the optimal parameter K corresponding to F1 is Ke1, the optimal parameter K corresponding to F2 is Ke2, the optimal parameter K corresponding to F3 is Ke3, and the optimal parameter K corresponding to F4 is Ke4. Then, the parameter K corresponding to the group is calculated according to the optimal parameters K corresponding to F1, F2, F3, and F4, that is, according to Ke1, Ke2, Ke3, and Ke4. Optionally, multiple approaches may be used to calculate the parameter K according to Ke1, Ke2, Ke3, and Ke4. The specific approach for the calculation is not limited here. The approach for calculating the parameter K corresponding to other groups is the same as the above, details of which will not be described again here.

Specifically, the process of determining the parameter K corresponding to the group according to the estimated value of the respective parameter K corresponding to each frequency point coefficient in the group includes: determining the parameter K corresponding to the group by acquiring and averaging the estimated value of the respective parameter K corresponding to each frequency point coefficient in the group.

For example, following the foregoing logic equations, after quantization, each frequency point coefficient in the same group has a corresponding optimal parameter K, that is Ke. The Ke corresponding to each frequency point coefficient in the same group after quantization are averaged to obtain the parameter K corresponding to the group. For example, the aforementioned group includes F1, F2, F3, and F4. The optimal parameters K corresponding to F1, F2, F3, and F4 are respectively Ke1, Ke2, Ke3, and Ke4. According to Ke1, Ke2, Ke3, and Ke4, one way to calculate the parameter K corresponding to the group is to average Ke1, Ke2, Ke3, and Ke4 to obtain an average value, which is considered as the parameter K corresponding to the group. The approach for calculation of the parameter K corresponding to other groups is the same, details of which are not repeated again here. The parameters K corresponding to different groups may be the same or different.

Step S706: Perform a K-th Exp-Golomb encoding on each frequency point coefficient in each group according to the parameter K corresponding to each group.

Taking the quantized frequency point coefficient FQ as an example, the calculation on FQ using the K-th Exp-Golomb encoding is as follows:

Me=(Sign(FQ)!=0)?2*Level(FQ)−Sign(FQ):2*Level(FQ)

where

Sign(FQ)=(FQ<0)?1:0,Level(FQ)=(FQ<0)?−FQ:FQ.

The result of the K-th Exp-Golomb encoding on FQ includes two code words. One code word is denoted by “a” and the other code word is denoted by “b”. Specifically, the code word “a” precedes the code word “b”. That is, the K-th Exp-Golomb encoded FQ is “ab”. The code word length of the code word “a” is (Me/2^{K})+1, and the code word value of the code word “a” is 1. The code word length of the code word “b” is K, and the code word value of the code word “b” is Me & (2^{K}−1). Assume that the code word length of the code word “a” is 3, the code word length of the code word “b” is 2, and the code word value of the code word “b” is 11, then the K-th Exp-Golomb encoded FQ is 00111. The encoding process of other frequency point coefficients after quantization is similar to the above, details of which are not described again here.

For example, the M*N number of frequency point coefficients are divided into H groups, and the quantization step corresponding to each group is Q. The parameter K corresponding to the first group is K1, the parameter K corresponding to the second group is K2, . . . , and the parameter K corresponding to the H-th group is KH. When performing the K-th Exp-Golomb encoding on the M*N number of frequency point coefficients, the quantization step Q corresponding to each group, the parameter K corresponding to the first group (i.e., K1), each quantized frequency point coefficient in the first group, the parameter K corresponding to the second group (i.e., K2), each quantized frequency point coefficient in the second group, . . . , the parameter K corresponding to the H-th group (i.e., KH), and each quantized frequency point coefficient in the H-th group may be encoded in turn. In this way, the encoded radar data includes a quantization step corresponding to each group, parameter K corresponding to each group, and the code words after the K-th Exp-Golomb encoding for each frequency point coefficient in each group.

If the quantization step Q corresponding to each group is the same, the specific storage format of the encoded radar data may be: Q, K1, encoded results of K1, K2, encoded results of K2, . . . , KH, and encoded results of KH.

If the quantization step Q of each group is different, for example, the quantization step of the first group is Q1, the quantization step of the second group is Q2, . . . , and the quantization step of the H-th group is QH, then the specific storage format of the encoded radar data may be: Q1, K1, encoded results of K1, Q2, K2, encoded results of K2, . . . , QH, KH, and encoded results of KH.

In one example, the UAV is the transmission terminal of the encoded radar data, and the ground-side device is the receiving terminal. When grouping the ranked frequency point coefficients, the predefined grouping method used by the UAV may be one of a plurality of predefined grouping methods. If the predefined grouping method used by the UAV is not a grouping method agreed between the UAV and the ground-side device, when the UAV encodes the radar data, the identification information of the predefined grouping method used by the UAV also needs to be encoded. That is, the encoded radar data also includes the identification information of the predefined grouping method used by the UAV when grouping the ranked frequency point coefficients. In this way, when the ground-side device receives the encoded radar data and decodes the encoded radar data, the ground-side device may parse out the predefined grouping method used by the UAV. This then allows the ground-side device to use the same grouping method to group the decoded radar data. If the predefined grouping method used by the UAV is a grouping method agreed between the UAV and the ground-side device, it is not necessary to encode the identification information of the predefined grouping method used by the UAV.

Step S707: Store the encoded radar data.

After encoding each group, the UAV further stores the encoded radar data, thereby accomplishing the compression and storage of the radar data.

In the disclosed embodiment, a two-dimensional FFT is performed on the original radar data measured by the radar device to obtain frequency point coefficients of the original radar data. After ranking and grouping the frequency point coefficients, the frequency points with close energy amplitudes are grouped into a same group. After grouping, each group shares a K value. Each frequency point coefficient in each group is further quantized, and the K-th Exp-Golomb encoding is performed on each quantized frequency point coefficient in each group. This improves the radar data compression efficiency.

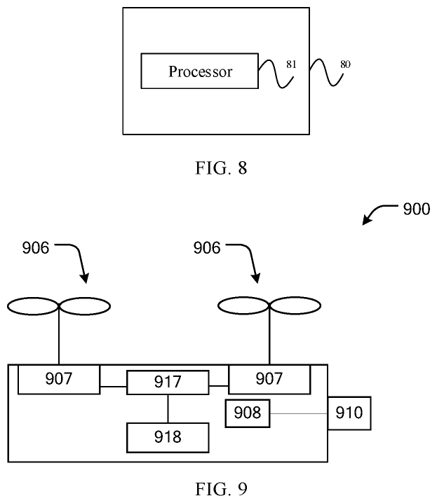

An embodiment of the present disclosure provides a radar data processing device. FIG. 8 is a structural diagram of a radar data processing device according to an embodiment of the present disclosure. As shown in FIG. 8, the radar data processing device 80 includes a processor 81, which is configured to divide to-be-compressed data into groups, determine encoding parameters of each group according to at least one radar data in each group, and encode each radar data in each group according to the encoding parameters of each group, to obtain encoded radar data.

The specific principles and implementations of the radar data processing device provided by this embodiment are similar to the embodiment shown in FIG. 1, details of which are not described again here.

In the disclosed embodiment, the to-be-compressed radar data is divided into groups. The encoding parameters for each group are determined according to at least one radar data in each group. Each radar data in each group is encoded, to obtain the encoded radar data. Through encoding radar data in groups, encoding efficiency for each group is improved, thereby achieving an efficient compression of the radar data.

An embodiment of the present disclosure provides a radar data processing device. Based on the technical solutions provided by the embodiment shown in FIG. 8, optionally, after encoding each radar data in each group according to the encoding parameters of each group to obtain the encoded radar data, the processor 81 is further configured to store the encoded radar data in a memory.

Optionally, before dividing the to-be-compressed radar data into groups, the processor 81 is further configured to perform a decorrelation transform on the original radar data measured by the radar device to obtain the decorrelation-transformed radar data, and determine the to-be-compressed radar data according to the decorrelation-transformed radar data.

Optionally, when determining the to-be-compressed radar data according to the decorrelation-transformed radar data, the processor 81 is specifically configured to use the decorrelation-transformed radar data as the to-be-compressed radar data.

Optionally, when determining the to-be-compressed radar data according to the decorrelation-transformed radar data, the processor 81 is specifically configured to rank the decorrelation-transformed radar data to obtain ranked radar data, and use the ranked radar data as the to-be-compressed radar data.

Optionally, when ranking the decorrelation-transformed radar data to obtain the ranked radar data, the processor 81 is specifically configured to rank the decorrelation-transformed radar data according to the frequency of the decorrelation-transformed radar data, to obtain the ranked radar data.

Optionally, when ranking the decorrelation-transformed radar data to obtain the ranked radar data, the processor 81 is specifically configured to rank the decorrelation-transformed radar data in an order of low-to-high frequency to obtain the ranked radar data.

Optionally, when ranking the decorrelation-transformed radar data in an order of low-to-high frequency, the processor 81 is specifically configured to perform a ZigZag scan on the decorrelation-transformed radar data in an order of low-to-high frequency.

The specific principles and implementations of the radar data processing device provided by this embodiment are similar to the embodiment shown in FIG. 4, details of which are not described again here.

In the disclosed embodiment, the decorrelation transform is performed on the original radar data measured by the radar device to obtain the decorrelation-transformed radar data. By compressing the decorrelation-transformed radar data, the compression efficiency of the radar data may be further improved.

An embodiment of the present disclosure provides a radar data processing device. Based on the technical solutions provided by the embodiment shown in FIG. 8, when the processor 81 performs the decorrelation transform on the original radar data measured by the radar device to obtain the decorrelation-transformed radar data, the processors 81 is specifically configured to perform a two-dimensional FFT on the original radar data measured by the radar device to obtain frequency point coefficients of the original radar data.

Correspondingly, when determining the to-be-compressed radar data according to the decorrelation-transformed radar data, the processor 81 is specifically configured to determine to-be-compressed frequency point coefficients according to the frequency point coefficients of the original radar data.

Optionally, when determining the to-be-compressed frequency point coefficients according to the frequency point coefficients of the original radar data, the processor 81 is specifically configured to rank the frequency point coefficients of the original radar data to obtain the ranked frequency point coefficients, and use the ranked frequency point coefficients as the to-be-compressed frequency point coefficients.

Optionally, when ranking the frequency point coefficients of the original radar data to obtain the ranked frequency point coefficients, the processor 81 is specifically configured to rank the frequency point coefficients of the original radar data in an order of low-to-high frequency, to obtain the ranked frequency point coefficients.

Optionally, when ranking the frequency point coefficients of the original radar data in an order of low-to-high frequency, the processor 81 is specifically configured to perform a ZigZag scan on the frequency point coefficients of the original radar data in an order of low-to-high frequency.

Optionally, when dividing the to-be-compressed radar data into groups, the processor 81 is specifically configured to divide the ranked frequency point coefficients into groups, where each group includes at least one frequency point coefficient.

Optionally, the number of frequency point coefficients included in each group is the same or different.

Optionally, when determining the encoding parameters of each group according to at least one radar data in each group, the processor 81 is specifically configured to, determine parameter K corresponding to each group according to each frequency point coefficient in each group when performing the K-th Exp Golomb encoding on each group.

Optionally, in determining the parameter K corresponding to each group according to each frequency point coefficient in each group when performing the K-th Exp Golomb encoding on each group, the processor 81 is specifically configured to determine an estimated value of the parameter K corresponding to each frequency point coefficient according to each frequency point coefficient in the group, and determine the parameter K corresponding to the group according to the estimated value of the parameter K corresponding to each frequency point coefficient in the group.

Optionally, when determining the parameter K corresponding to the group according to the estimated value of the parameter K corresponding to each frequency point coefficient in the group, the processor 81 is specifically configured to average the estimated values of the corresponding parameters K for the frequency point coefficients in the group to obtain the parameter K corresponding to the group.

Optionally, when encoding the radar data in each group according to the encoding parameters of each group, the processor 81 is specifically configured to perform a K-th Exp Golomb encoding on each frequency point in each group according to the parameter K corresponding to each group.

Optionally, the encoded radar data includes parameter K corresponding to each group and code words after the K-th Exp Golomb encoding of each frequency point coefficient in each group.

Optionally, before encoding the radar data in each group according to the encoding parameters of each group, the processor 81 is further configured to quantize each frequency point coefficient in each group according to the quantization step corresponding to each group.

Optionally, the quantization steps corresponding to different groups may be the same or different.

Optionally, the quantization steps of some frequency point coefficients in a group are not the same.

Optionally, the encoded radar data includes quantization step corresponding to each group, parameter K corresponding to each group, and code words after the K-th Exp Golomb encoding for each frequency point coefficient in each group.

Optionally, the encoded radar data further includes identification information of a predefined grouping method used by the UAV when grouping the ranked frequency point coefficients.

The specific principles and implementations of the radar data processing device provided by this embodiment are similar to the embodiment shown in FIG. 7, details of which are not described again here.

In the disclosed embodiment, a two-dimensional FFT is performed on the original radar data measured by the radar device to obtain frequency point coefficients of the original radar data. After ranking and grouping the frequency point coefficients, the frequency points with close energy amplitudes are grouped into a same group. After grouping, each group shares a K value. Each frequency point coefficient in each group is further quantized, and the K-th Exp-Golomb encoding is performed on each quantized frequency point coefficient in each group. This improves the radar data compression efficiency.

An embodiment of the present disclosure provides a mobile platform. The mobile platform includes a fuselage, a propulsion system installed on the fuselage for providing propulsion for motion, a radar device for detecting target objects around the mobile platform, and a radar data processing device according to the foregoing embodiments. Optionally, the mobile platform includes at least one of the following: a UAV, a mobile robot, and a vehicle.

An embodiment of the present disclosure provides a UAV. FIG. 9 is a structural diagram of a UAV according to an embodiment of the present disclosure. As shown in FIG. 9, the UAV 900 includes a fuselage, a propulsion system, a radar device 910, a radar data processing device 908, and a flight controller 918. The propulsion system includes at least one of the following: a motor 907, a propeller 906, and an electronic speed controller 917. The propulsion system is installed on the fuselage for providing flight propulsion. The flight controller 918 is communicatively connected to the propulsion system for controlling the flight of the UAV.

Specifically, the specific principles and implementations of the radar data processing device 908 are similar to the foregoing embodiments, details of which are not repeated again here.

In this embodiment, the to-be-compressed radar data is divided into groups. The encoding parameters of each group are determined according to at least one radar data in each group. The radar data in each group is encoded according to the encoding parameters of each group, to obtain the encoded radar data. By encoding the radar data in groups, the encoding efficiency of each group is improved, thereby achieving an efficient compression of the radar data.

It should be noted that, in the embodiments provided by the present disclosure, the disclosed devices and methods may be implemented in alternative approaches. For example, the foregoing device embodiments described above are merely for illustrative purposes. For another example, the division of the units is merely a logical function division. In actual implementations, other division approaches may also be considered. For another example, multiple units or components may be combined or may be integrated into another system, or some features may be ignored or not implemented. In addition, the displayed or discussed mutual coupling or direct coupling or communication connection may be indirect coupling or communication connection through some interfaces, devices or units, which may be electrical, mechanical or other forms.

The units described as separate components may or may not be physically separated, and the components displayed as units may or may not be physical units, that is, may be located in one place, or may be distributed across multiple network units. Some or all of the units may be selected according to the actual needs to achieve the objective of the disclosed embodiments.

In addition, each functional unit in each embodiment of the present disclosure may be integrated into one processing unit, or each unit may exist physically and separately, or two or more units may be integrated into one unit. The above integrated unit may be implemented in the form of hardware, or in the form of hardware plus a software functional unit.

The above integrated unit implemented in the form of a software functional unit may be stored in a computer-readable storage medium. The above software functional unit is stored in the storage medium and includes a series of instructions that are configured to cause a computer device (which may be a personal computer, a server, or a network device) or a processor to execute some steps of the methods described in the embodiments of the present disclosure. The aforementioned storage media include a flash device, a mobile drive, a read-only memory (ROM), a random-access memory (RAM), a magnetic disk, an optical disk, or other media that can store program code.

Those skilled in the art may clearly understand that for the convenience and brevity of the description, only the above-mentioned division of the functional modules is illustrated for exemplary purposes. In practical applications, the aforementioned functions may be allocated by different functional modules according to the actual needs. That is, the internal structure may be divided into different functional modules to complete all or part of the functions described above. For the specific working processes of the devices described above, reference may be made to the corresponding processes in the foregoing method embodiments, details of which are not described again here.

Further, it should be noted that the foregoing embodiments are only used to illustrate the technical solutions of the present disclosure, but are not limited thereto. Although the present disclosure has been described in detail with reference to the foregoing embodiments, those skilled in the art should understand that the technical solutions described in the foregoing embodiments may still be modified, or some or all of the technical features may be equivalently substituted. These modifications or substitutions do not deviate the spirits and principles of the corresponding technical solutions from the coverage of the technical solutions of the embodiments of the present disclosure.

What is claimed is:

1. A radar data processing method, comprising:
dividing to-be-compressed radar data into groups;
determining encoding parameters of each group according to at least one radar data in each group; and
according to the encoding parameters of each group, encoding each radar data in each group to obtain encoded radar data.

2. The method according to claim 1, wherein, after encoding each radar data in each group according to the encoding parameters of each group to obtain the encoded radar data, the method further includes:
storing the encoded radar data.

3. The method according to claim 1, wherein, before dividing the to-be-compressed radar data into groups, the method further includes:
performing a decorrelation transform on original radar data measured by a radar device to obtain decorrelation-transformed radar data; and
determining the to-be-compressed radar data according to the decorrelation-transformed radar data.

4. The method according to claim 3, wherein determining the to-be-compressed radar data according to the decorrelation-transformed radar data further includes:
determining the decorrelation-transformed radar data as the to-be-compressed radar data.

5. The method according to claim 3, wherein determining the to-be-compressed radar data according to the decorrelation-transformed radar data further includes:
ranking the decorrelation-transformed radar data to obtain ranked radar data; and
determining the ranked radar data as the to-be-compressed radar data.

6. The method according to claim 5, wherein ranking the decorrelation-transformed radar data to obtain the ranked radar data further includes:
ranking the decorrelation-transformed radar data according to a frequency of the decorrelation-transformed radar data to obtain the ranked radar data.

7. The method according to claim 6, wherein ranking the decorrelation-transformed radar data to obtain the ranked radar data further includes:
ranking the decorrelation-transformed radar data in an order of low-to-high frequency to obtain the ranked radar data.

8. The method according to claim 7, wherein ranking the decorrelation-transformed radar data in an order of low-to-high frequency further includes:
performing a ZigZag scan on the decorrelation-transformed radar data in an order of low-to-high frequency.

9. The method according to claim 3, wherein:
performing a decorrelation transform on the original radar data measured by the radar device to obtain the decorrelation-transformed radar data further includes:
performing a two-dimensional Fast Fourier Transform on the original radar data measured by the radar device to obtain frequency point coefficients of the original radar data; and
determining the to-be-compressed radar data according to the decorrelation-transformed radar data further includes:
determining to-be-compressed frequency point coefficients according to the frequency point coefficients of the original radar data.

10. The method according to claim 9, wherein determining the to-be-compressed frequency point coefficients according to the frequency point coefficients of the original radar data further includes:
ranking the frequency point coefficients of the original radar data to obtain ranked frequency point coefficients; and
using the ranked frequency point coefficients as the to-be-compressed frequency point coefficients.

11. The method according to claim 10, wherein ranking the frequency point coefficients of the original radar data to obtain the ranked frequency point coefficients further includes:
ranking the frequency point coefficients of the original radar data in an order of low-to-high frequency to obtain the ranked frequency point coefficients.

12. The method according to claim 11, wherein ranking the frequency point coefficients of the original radar data in an order of low-to-high frequency further includes:
performing a ZigZag scan on the frequency point coefficients of the original radar data in an order of low-to-high frequency.

13. The method according to claim 10, wherein dividing the to-be-compressed radar data into groups further includes:
dividing the ranked frequency point coefficients into groups, each group including at least one frequency point coefficient.

14. The method according to claim 13, wherein:
the number of frequency point coefficients included in each group is the same; or
the number of frequency point coefficients included in each group is different.

15. The method according to claim 1, wherein determining the encoding parameters of each group according to at least one radar data in each group further includes:
according to each frequency point coefficient in each group, determining parameter K corresponding to each group when performing a K-th Exp-Golomb encoding on each group.

16. The method according to claim 15, wherein determining the parameter K corresponding to each group when performing the K-th Exp-Golomb encoding on each group according to each frequency point coefficient in each group further includes:
determining, according to each frequency point coefficient in the group, an estimated value of the parameter K corresponding to each frequency point coefficient; and
determining the parameter K corresponding to the group according to the estimated values of parameters K corresponding to the respective frequency point coefficients in the group.

17. The method according to claim 16, wherein determining the parameter K corresponding to the group according to the estimated values of the parameters K corresponding to the respective frequency point coefficients in the group further includes:
averaging the estimated values of the parameters K corresponding to the respective frequency point coefficients in the group to obtain the parameter K corresponding to the group.

18. The method according to claim 15, wherein encoding each radar data in each group according to the encoding parameters of each group further includes:
performing the K-th Exp-Golomb encoding on each frequency point coefficient in each group according to the parameter K corresponding to each group.

19. A radar data processing device, comprising a processor that is configured to:
divide to-be-compressed radar data into groups;
determine encoding parameters of each group according to at least one radar data in each group; and
according to the encoding parameters of each group, encode each radar data in each group to obtain encoded radar data.

20. A mobile platform, comprising:
a fuselage;
a propulsion system installed on the fuselage for providing propulsion for motion;
a radar device for detecting target objects around the mobile platform; and
a radar data processing device including a processor configured to:
divide to-be-compressed radar data into groups,
determine encoding parameters of each group according to at least one radar data in each group, and
according to the encoding parameters of each group, encode each radar data in each group to obtain encoded radar data.
